(19) United States
(12) Patent Application Publication
(10) Pub. No.: US 2025/0326629 A1
(43) Pub. Date: Oct. 23, 2025

(54) Monolithic Microelectromechanical Systems Based Spatial Light Modulators Including Ribbon-Type Modulators

(71) Applicant: SILICON LIGHT MACHINES CORPORATION, San Jose, CA (US)

(72) Inventors: James Hunter, Campbell, CA (US); Alexander Payne, Ben Lommond, CA (US); Tianbo Liu, San Jose, CA (US); Lars Eng, Los Altos, CA (US); Stephen Hamann, Mountain View, CA (US)

(73) Assignee: SILICON LIGHT MACHINES CORPORATION, San Jose, CA (US)

(21) Appl. No.: 19/098,563

(22) Filed: Apr. 2, 2025

Related U.S. Application Data
(60) Provisional application No. 63/573,086, filed on Apr. 2, 2024.

(51) Int. Cl. B81B 3/00; B81C 1/00; G02B 26/08

(52) U.S. Cl. CPC B81B 3/0086; B81C 1/00246; G02B 26/0841; B81B 2201/047; B81B 2203/04; B81B 2207/015; B81B 2207/053; B81B 2207/056; B81B 2207/07; B81B 2207/096; B81C 2201/0107; B81C 2201/0133; B81C 2201/0164; B81C 2201/0176; B81C 2201/0181

(57) ABSTRACT

Monolithic microelectromechanical systems (MEMS) based spatial light modulators (SLM) including ribbon-type modulators and drivers integrally fabricated in or on a common substrate are provided. Generally, the monolithic MEMS-based SLM includes a common electrode in or on a substrate, a number of electrostatically displaceable ribbons, each including a tensile, amorphous silicon-germanium layer (SiGe layer) that serves as a structural layer and as a ribbon electrode, and a light reflective surface on the SiGe layer facing away from the surface on the substrate. A driver including a plurality of drive channels monolithically integrated in the substrate below the surface, the driver electrically coupled to the common electrode and each ribbon electrode and operable to apply voltages thereto to drive the plurality of ribbons to modulate light reflected from the light reflective surfaces.

### CROSS-REFERENCE TO RELATED APPLICATIONS

This application claims the benefit of priority under 35 U.S.C. 119 (e) to U.S. Provisional Patent Application Ser. No. 63/573,086 filed Apr. 2, 2024, which is incorporated by reference herein in its entirety.

### TECHNICAL FIELD

This disclosure relates generally relates to spatial light modulators (SLMs), and more particularly to an integrated or monolithic microelectromechanical systems (MEMS) based SLMs including ribbon-type modulators and a driver integrally fabricated in or on a common substrate.

### BACKGROUND

Spatial light modulators (SLMs) include an array of one or more modulators that can control or modulate an incident beam of light in a spatial pattern that corresponds to an electrical input to the modulators. One type of SLM, a reflective SLM, uses a number of movable reflective surfaces to modulate an intensity, phase, polarization or direction a light beam from a coherent light source. Such SLMs are increasingly being developed for use in various applications, including display systems, optical information processing and data storage, printing, maskless lithography, 3D printing, additive manufacturing, surface modification and optical phase modulation.

One type of reflective SLM potentially useful in the aforementioned applications is an electronically addressable, reflective, ribbon-type microelectromechanical systems (MEMS) based SLM, such as a Grating Light Valve (GLV™) commercially available from Silicon Light Machines, in San Jose CA.

This ribbon-type SLM generally includes an array of active-ribbons suspended over a surface of a substrate, each ribbon having a first, light reflective surface that may be moved or deflected relative to a another ribbon or to a second, passive or static light reflective surface that be formed on a surface of the substrate or on a static ribbon. Each active-ribbon and adjacent static light reflective surface forms a single diffractor or ribbon-pair. The ribbon-type SLM modulates incident light by deflecting one or more of active-ribbons in the array relative to the second, passive or static light reflective surface towards the surface of the substrate, bringing a coherent light reflected from the active light reflective surface into interference with coherent light reflected from the static light reflective surface. The electrostatic force generated by a drive voltage from a drive-circuitry or driver coupled to the substrate-electrode and ribbon-electrodes.

Generally, the driver is implemented as integrated circuit (IC) using (CMOS) technology. Because many of the materials and process parameters used to fabricate the drive-circuit are incompatible with those needed to fabricate MEMS modulators, MEMS-based SLMs often include a separate die or substrate on which the driver is fabricated wire bonded to a MEMS die on which the array of MEMS modulators (MEMS array) are fabricated, and packaged in a multi-chip module. However, this leads to slower switching speeds, lower drive channel counts, higher power consumption and decreased yields due wire bond failure.

Some success has been realized by fabricating the driver on a common substrate laterally separated from the array of the MEMS-based SLM. Generally, this involves either fabricating the driver first or modifying the CMOS process flow and architecture to fabricate the array at least partially concurrently with drive-circuit. However, this typically negatively impacts the functioning of the drive-circuit, the MEMS modulators or both. In particular, it is noted that the high temperature deposition processes used to fabricate the MEMS modulators deleteriously modifies diffusions and silicides in CMOS transistors, and damages metal layers and vias. Additionally, metal and dielectric layers of the driver can be further damaged by etching and polishing steps used to fabricate the MEMS modulators. Finally, the top light reflective surfaces, which are polished by CMP, of the MEMs modulators, have a lower height above the surface of the substrate than the driver, limiting the number of CMOS layers that can be used, restricting driver functionality and hindering layout.

Accordingly, there is a need for a monolithic MEMS-based SLMs including a driver integrated in a common substrate with the modulators of the SLM. It is further desirable the integration not restrict layout or interfere with functioning of the driver.

### SUMMARY

An integrated or monolithic microelectromechanical systems (MEMS) based spatial light modulator (SLM) including ribbon-type modulators and a driver integrally fabricated in or on a common substrate is provided. Generally, the monolithic MEMS-based SLM includes a common electrode in or on a substrate, a number of electrostatically displaceable ribbons, each including a layer of tensile, amorphous silicon-germanium (SiGe layer) that serves as a structural layer and as a ribbon electrode, and a light reflective surface on the SiGe layer facing away from the surface on the substrate. A driver including a plurality of drive channels monolithically integrated in the substrate below the surface, the driver electrically coupled to the common electrode and each ribbon electrode and operable to apply drive voltages thereto to drive the plurality of ribbons to modulate light reflected from the light reflective surfaces.

In some embodiments, the monolithic MEMS-based SLM is a phase modulator and includes an array of parallel ribbons in which every ribbon is an electrostatically displaceable ribbon. The electrostatically displaceable ribbons are grouped to form a plurality of pixels, each pixel including a number of adjacent electrostatically displaceable ribbons. When operated as a phase modulator, the driver of the MEMS-based SLM is operable to individually drive the number of adjacent electrostatically displaceable ribbons in each of the plurality of pixels to deflect each of the number of adjacent electrostatically displaceable ribbons in the pixel by a monotonically varying distance to modulate a phase of light incident thereon.

Further features and advantages of embodiments of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to a person skilled in the relevant art(s) based on the teachings contained herein.

### BRIEF DESCRIPTION OF THE DRAWINGS

Embodiments of the invention will now be described, by way of example only, with reference to the accompanying schematic drawings in which corresponding reference symbols indicate corresponding parts. Further, the accompanying drawings, which are incorporated herein and form part of the specification, illustrate embodiments of the present invention, and, together with the description, further serve to explain the principles of the invention and to enable a person skilled in the relevant art(s) to make and use the invention.

FIG. 1 is a schematic block diagram illustrating a cross-sectional view of a monolithic microelectromechanical systems (MEMS)-based spatial light modulator (SLM) including a driver integrally fabricated in a substrate and an array of ribbon-type modulators fabricated on top thereof;

FIG. 2A is a perspective view of a portion of a MEMS-based SLM suitable for amplitude modulation of incident light and including ribbon-type modulators according to an embodiment of the present disclosure;

FIG. 2B is a schematic block diagram of sectional side view of the ribbon-type modulators of FIG. 2A;

FIG. 3A is a perspective view of a portion of another embodiment of a MEMS-based SLM including ribbon-type modulators suitable for phase modulation of incident light;

FIG. 3B is a schematic block diagram of sectional side views of the ribbon-type modulators of FIG. 3A;

FIG. 4A is a schematic block diagram of a planar top view of a monolithic MEMS-based SLM including a linear array of ribbon-type modulators and a driver integrally fabricated in a substrate below the modulators;

FIG. 4B is a schematic side view of a deflected active-ribbon of the MEMS-based SLM of FIG. 4A;

FIGS. 5A and 5B are optic diagrams illustrating illumination and imaging light paths for an optical system including a monolithic MEMS-based SLM;

FIG. 6 is a flowchart of a method for fabricating a monolithic MEMS-based SLM including ribbon-type modulators, such as shown in FIG. 2A or 3A; and

FIGS. 7A and 7B illustrate an intermediate MEMS structure of the MEMS-based SLM including ribbon-type modulators formed by the method of FIG. 6.

The features and advantages of embodiments of the present invention will become more apparent from the detailed description set forth below when taken in conjunction with the drawings. In the drawings, like reference numbers generally indicate identical, functionally similar, and/or structurally similar elements.

### DETAILED DESCRIPTION

Embodiments of an integrated or monolithic microelectromechanical systems (MEMS)-based spatial light modulators (SLM) including ribbon-type MEMS-based light modulators formed on a surface of a substrate overlying a driver integrally formed in the substrate below the modulators, and methods for fabricating and using the same are provided.

In the following description, numerous specific details are set forth, such as specific materials, dimensions and processes parameters etc. to provide a thorough understanding of the present invention. However, particular embodiments may be practiced without one or more of these specific details, or in combination with other known methods, materials, and apparatuses. In other instances, well-known semiconductor design and fabrication techniques have not been described in particular detail to avoid unnecessarily obscuring the present invention. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, materials, or characteristics may be combined in any suitable manner in one or more embodiments.

The terms “over,” “under,” “between,” and “on” as used herein refer to a relative position of one layer with respect to other layers. As such, for example, one layer deposited or disposed over or under another layer may be directly in contact with the other layer or may have one or more intervening layers. Moreover, one layer deposited or disposed between layers may be directly in contact with the layers or may have one or more intervening layers. In contrast, a first layer “on” a second layer is in contact with that second layer. Additionally, the relative position of one layer with respect to other layers is provided assuming operations deposit, modify and remove films relative to a starting substrate without consideration of the absolute orientation of the substrate.

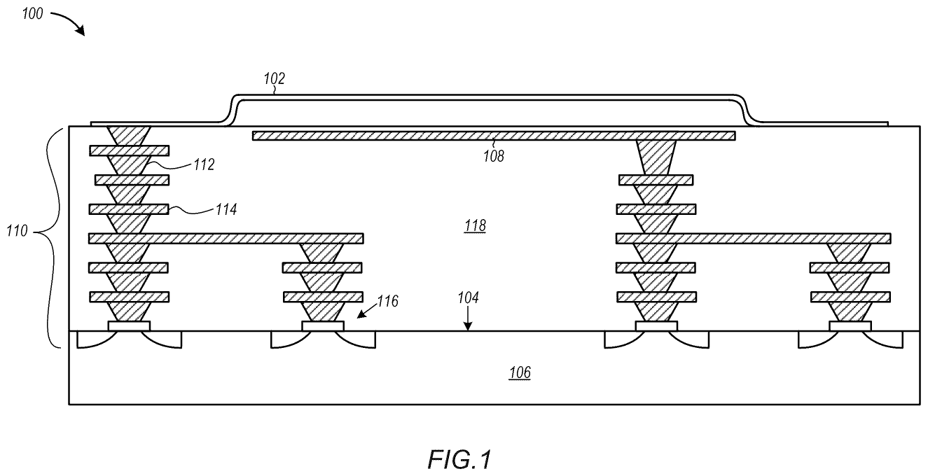

FIG. 1 is a schematic block diagram illustrating a cross-sectional view of a monolithic MEMS-based SLM including an array of ribbon-type MEMS-based light diffractors or modulators, and a driver integrally fabricated in a substrate underlying the modulators. Briefly, referring to FIG. 1 the monolithic MEMS-based SLM 100 includes a number of ribbon-type modulators 102 (only one ribbon of which is shown) formed on or overlying a surface 104 of a substrate 106, a common electrode 108 formed in or on the surface of the substrate, and a driver 110 integrally formed in and on the substrate below the ribbon-type modulators. The driver 110 generally includes multiple layers of vias 112, metal layers 114, and devices or transistors 116 fabricated in the substrate 106 and in a number of dielectric layers 118 overlying the surface of the substrate using a complementary metal-oxide-semiconductor (CMOS) technology. Generally, the driver 110 includes as many as six to eight metal interconnect layers, and lies partially or completely under one or more of the ribbon-type modulators 102 and the common electrode 108, and the ribbon-type modulators 102 each include a number of electrostatically displaceable ribbons suspended above an upper surface of the substrate. The driver 110 is coupled to the common electrode 108 and to deflectable ribbons in the ribbon-type modulators 102 through a number vias 112 and/or metal layers 114.

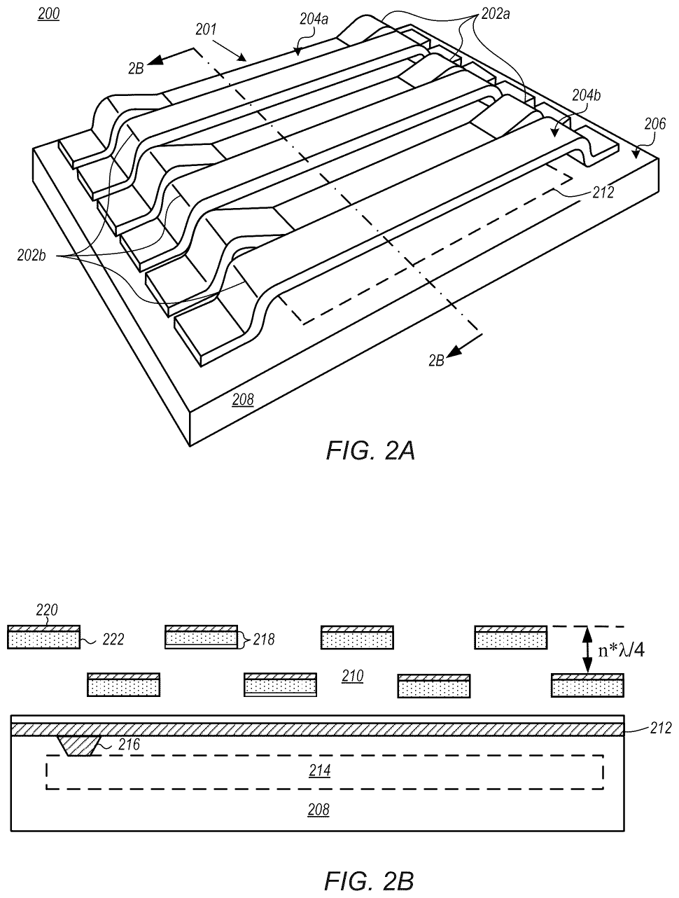

A first embodiment of a ribbon-type diffractor or modulator, such as a GLV™, suitable for use in a monolithic MEMS-based SLM will now be described with reference to FIGS. 2A and 2B. For purposes of clarity, many of the details of suitable for use in a monolithic MEMS-based SLM and modulators that are widely known and are not relevant to the present invention have been omitted from the following description. The drawings described are only schematic and are non-limiting. In the drawings, the size of some of the elements may be exaggerated and not drawn to scale for illustrative purposes. The dimensions and the relative dimensions may not correspond to actual reductions to practice of the invention.

FIG. 2A is a perspective view of a portion of a monolithic MEMS-based SLM 200 including ribbon-type modulators that is particularly suitable for amplitude modulation of incident light. FIG. 2B is a schematic sectional side view of the modulator of FIG. 2A taken perpendicular to a longitudinal axis of the ribbons.

Referring to FIGS. 2A and 2B, a monolithic MEMS-based SLM 200 generally includes an array 201 of a number of interleaved or interdigitated ribbons 202a, 202b; each having a light reflective surface 204a, 204b supported over a surface 206 of a substrate 208. One or more of the ribbons 202a are movable or deflectable through a gap 210 toward the substrate 208 to form an addressable diffraction grating with adjustable diffraction strength. The ribbons are 202a deflected towards the surface 206 of the substrate 208 by electrostatic forces generated when a drive voltage is applied between a ribbon electrode (not shown) in the electrostatically deflectable ribbons 202a and a common electrode 212 formed in or on the substrate and underlying all of the deflectable ribbons 202a. The applied drive voltages are controlled by drive circuit or driver 214 integrally formed in or on a surface overlying the substrate 208 and underlying at least some of the ribbons 202a, 202b. The driver 214 is electrically coupled to the common electrode 212 through a number of vias 216, and individually coupled to each of the deflectable ribbons 202a through a number of separate vias and high voltage nodes at ends of the deflectable ribbons (not shown in these figures).

The deflectable ribbons 202a can be displaced by n*λ/4 wavelength, where λ is a particular wavelength of light incident on the monolithic MEMS-based SLM 200, and n is an odd integer equal to or greater than 0. Moving the deflectable ribbons 202a brings light reflected from the first reflective surfaces 204a into constructive or destructive interference with light reflected by the second light reflective surfaces 204b formed on the stationary ribbons 202b, thereby modulating light incident on the monolithic MEMS-based SLM 200. The light reflected from the deflectable ribbons 202a adds as vectors of magnitude and phase with that reflected from stationary ribbons 202b or a reflective portion of the surface 206 beneath the ribbons. Generally, the driver 214 is operable to electrostatically displace the deflectable ribbons 202a continuously over an analog range of distances, thereby enabling full gray-scale control of an intensity or amplitude of light reflected from the monolithic MEMS-based SLM 200, limited only by a resolution and voltage levels of the driver 214.

Referring to FIG. 2B, each of the ribbons 202a, 202b, includes an mechanical or structural layer 218 supporting the ribbon above the surface 206 of the substrate 208 and a reflective material or layer 220 overlying the structural layer to form the first and second reflective surfaces 204a, 204b.

Previous generations of light modulators used silicon-nitride (SiN) for structural or mechanical layers of the ribbons in ribbon-type modulators. However, the relatively high temperatures required for deposition of SiN, typically in excess of about 800 C, impeded if not substantially prevented monolithic integration of the driver with the ribbon modulators on a single substrate.

In contrast, and in accordance with the present disclosure, the structural layer 218 includes a taut, tensile, amorphous silicon-germanium (SiGe) layer 222, which when electrically coupled to the driver 214 also serves or functions as the ribbon electrode for the deflectable ribbons 202a. By tensile, amorphous SiGe layer 222 it is meant a layer of silicon-germanium with a molecular formula of the form Si₁₋ₓGeₓ that has been formed or processed to yield a layer substantially free of any crystalline structure, and having a modulus of elasticity from about 100 to about 120 GigaPascals (GPa), and more preferably about 110 GPa.

The SiGe layer 222 can be deposited using chemical vapor deposition (CVD), or plasma enhanced CVD (PECVD), at a temperature of less than about 500 C, and to a thickness of from about 1000 Å to about 2000 Å. Preferably, the SiGe layer 222 once formed undergoes further processing, including ion implanting with impurities at a concentration selected to change stress in the SiGe layer from a compressive stress to a tensile stress, which is desirable for making taut, yet elastic ribbons 202a, 202b, followed by a low temperature (less than about 500 C) annealing of the implanted SiGe layer. More preferably, the SiGe layer is implanted with a dopant, which serves not only to change the stress in the SiGe layer to tensile but also to form a conductive implanted SiGe layer that also functions as the ribbon electrode for the deflectable ribbons 202a. Suitable impurities and dopants include Boron (B), Aluminum (Al), Gallium (Ga), Indium (In), Silicon (Si), Gold (Au) Xenon (Xe) Nitrogen (N), and Argon (Ar), ion implanted to a concentration of about from about of about 1E13 atoms/cm³ to about of about 1E18 atoms/cm³.

The reflective layer 220, can include any suitable metallic, dielectric or semiconducting material compatible with standard MEMS fabrication technologies, and capable of being patterned using standard lithographic techniques to form the first and second reflective surfaces 204a, 204b. The reflective material of the first and second light reflective surfaces 204a, 204b, is selected so that the monolithic MEMS-based SLM 200 is operable to modulate light ranging from deep ultraviolet light (DUV) to near-infrared (NIR) at wavelengths from 350 nm to 2 μm. Suitable metallic reflective materials can include aluminum (Al), aluminum-copper (AlCu), gold (Au), silver (Ag) or any other suitably reflective metal. Generally, the reflective layer 220 is deposited using physical vapor deposition (PVD) to a thickness of about half that of the SiGe layer 222, or from about 500 Å to about 1000 Å. Alternatively, the reflector layer could comprise a multilayer dielectrics stack, whereby the layer count and total thickness is sufficient to achieve required reflectivity.

As noted above with reference to FIG. 1, the driver 214 generally includes multiple layers of vias, metal interconnect layers, and devices or transistors fabricated in the substrate 208 and in a number of dielectric layers overlying the surface of the substrate using CMOS technology.

Generally, the substrate 208 can be a wafer of any material suitable for the manufacture of MEMS and microelectronic devices, including, for example, silicon, gallium-arsenide, or other such semiconductor or dielectric materials. The common electrode 212 can include titanium/titanium-nitride (Ti/TiN), and the vias 216 and metal interconnect layers (not shown in these figures) electrically coupling the common electrode and deflectable ribbons 202a to the driver 214 can include one or more of silicon-germanium (SiGe), germanium (Ge), aluminum (Al), aluminum-copper (AlCu), or tungsten (W).

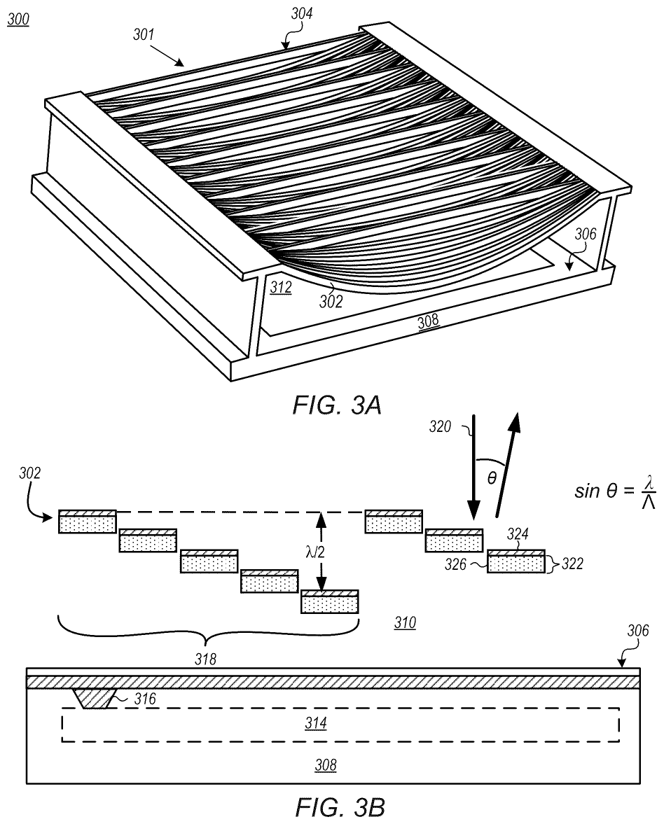

FIGS. 3A and 3B illustrate another embodiment of a MEMS-based SLM 300 including ribbon-type modulators, which is particularly suitable for phase modulation of incident light, but can also be operated for amplitude modulation or both amplitude and phase modulation. Referring to FIGS. 3A and 3B, the monolithic MEMS-based SLM 300 generally includes an array 301 of a number of ribbons 302, each having a light reflective surface 304 supported over a surface 306 of a substrate 308, all of which are movable or deflectable through a gap 310 toward the substrate. The ribbons are 302 deflected towards the surface 306 of the substrate 308 by electrostatic forces generated when a drive voltage is applied between a ribbon electrodes (not shown) in the ribbons 302 and a common electrode 312 formed in or on the substrate and the ribbons 302. The applied drive voltages are controlled by drive circuit or driver 314 integrally formed in or on a surface overlying the substrate 208, and underlying at least some of the ribbons 302. The driver 314 is electrically coupled to the common electrode 312 through a number of vias 316, and individually coupled to each of the ribbons 302 through a number of separate vias and high voltage nodes at ends of the ribbons (not shown in these figures).

FIG. 3B is a schematic representation of a portion of the monolithic MEMS-based SLM 300 of FIG. 3A shown in cross-section to long axes of the ribbons 302, when the modulator is operated as a phase modulator. Referring to FIG. 3B, the individual ribbons 302 are arranged into a number of groups 318 having a repeating pattern of pitch or period, defined or determined by the number of ribbons in the group. The deflection of each of ribbons 302 within a group 318 is monotonically varied for a maximum distance of between 0 and ½ of the wavelength (λ) of an incident light 320 to impart a monotonic phase variation of light reflected from each of the ribbons within the group. As explained in greater detail below, by sequentially shifting or varying the deflection of each ribbon in the array 301 the monolithic MEMS-based SLM 300 can be operated as a phase modulator to form a phase modulated beam of light, which can be scanned over an imaging plane or far field scene.

Referring to FIG. 3B, each of the ribbons 302, includes an mechanical or structural layer 322 supporting the ribbon above the surface 306 of the substrate 308 and a reflective material or layer 324 overlying the structural layer to form the reflective surfaces 304.

As noted above with reference to the embodiment of FIGS. 3A and 3B, the structural layer 322 includes a taut, tensile, conductive, amorphous silicon-germanium (SiGe) layer 326, which when electrically coupled to the driver 314 also serves or functions as the ribbon electrode for the ribbons 302. By tensile, amorphous SiGe layer 326 it is meant a layer of silicon-germanium with a molecular formula of the form Si₁₋ₓGeₓ that has been formed or processed to yield a layer substantially free of any crystalline structure, and having a modulus of elasticity from about 100 to about 120 GigaPascals (GPa), and more preferably about 110 GPa.

The SiGe layer 326 can be deposited using CVD or PECVD, at a temperature of about 500 C, and to a thickness of from about 1000 Å to about 2000 Å. Preferably, the SiGe layer 326 once formed undergoes further processing, including ion implanting with impurities at a concentration selected to change stress in the SiGe layer from a compressive stress to a tensile stress, which is desirable for making taut, yet elastic ribbons 302, followed by a low temperature (less than about 500 C) annealing of the implanted SiGe layer. More preferably, the SiGe layer is implanted with a dopant, which serves not only to change the stress in the SiGe layer to tensile but also to form a conductive SiGe layer that also functions as the ribbon electrode for the ribbons 302. Suitable impurities and dopants include Boron (B), Aluminum (Al), Gallium (Ga), Indium (In), Silicon (Si), Gold (Au) Xenon (Xe) Nitrogen (N), and Argon (Ar), ion implanted to a concentration of about from about of about 1E13 atoms/cm³ to about of about 1E18 atoms/cm³.

The reflective layer 324, can include any suitable metallic, dielectric or semiconducting material compatible with standard MEMS fabrication technologies, and capable of being patterned using standard lithographic techniques to form the reflective surfaces 304. The reflective material of the light reflective surfaces 304 is selected so that the monolithic MEMS-based SLM 200 is operable to modulate light ranging from deep ultraviolet light (DUV) to near-infrared (NIR) at wavelengths from 350 nm to 2 μm. Suitable reflective materials can include aluminum (Al), aluminum-copper (AlCu), gold (Au), silver (Ag) or any other suitably reflective metal. Generally, the reflective layer 324 is deposited using PVD to a thickness of about half that of the SiGe layer 326, or from about 500 Å to about 1000 Å.

The driver 314 generally includes multiple layers of vias, metal layers, and devices or transistors fabricated in the substrate 308 and in a number of dielectric layers overlying the surface of the substrate using CMOS technology.

The substrate 308 can be a wafer of any material suitable for the manufacture of MEMS and microelectronic devices, including, for example, silicon, gallium-arsenide, or other such semiconducting and dielectric materials. The common electrode 312 can include titanium/titanium-nitride (Ti/TiN), and the vias 216 and metal interconnect layers (not shown in these figures) electrically coupling the common electrode and ribbons 302 to the driver 314 can include one or more of silicon-germanium (SiGe), germanium (Ge), aluminum (Al), aluminum-copper (AlCu), or tungsten (W).

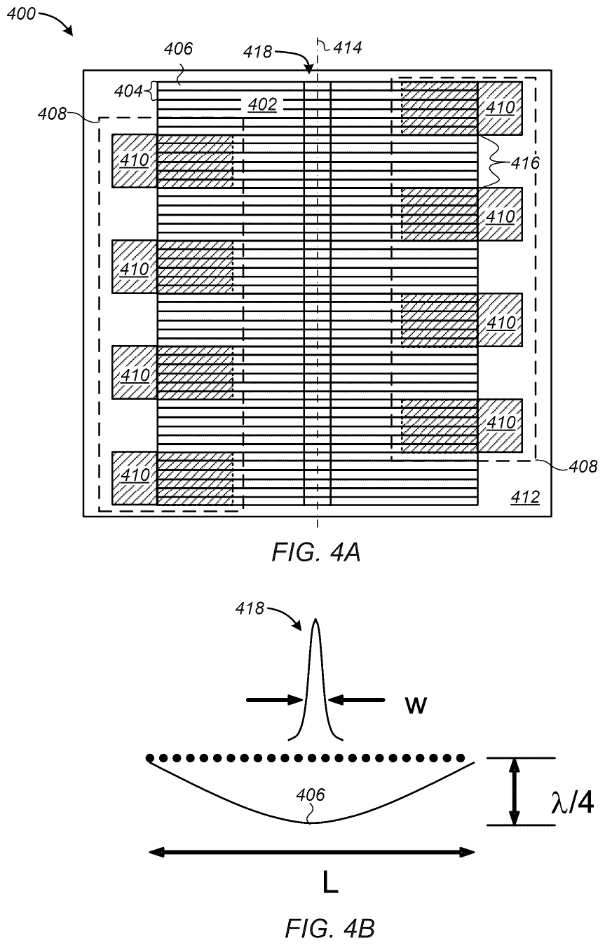

FIG. 4A is a schematic block diagram of a planar top view of a monolithic MEMS-based SLM 400 including a linear (1-dimensional) array 402 of ribbon-type diffractors or modulators 404, each including one or more ribbons 406 and a driver 408 including a number of individual drive channels 410 integrally fabricated in a substrate 412 below the modulators. In one embodiment, the monolithic MEMS-based SLM 400 is configured or operable as an amplitude modulator, and each modulator 404 consists of a number of active (movable) ribbons 406 are interlaced or paired with a number of static bias ribbons, as shown in FIGS. 2A and 2B above. By displacing the active ribbons 406 by a quarter wavelength (λ/4) relative to the static ribbons light reflected from the active ribbons interferes with that reflected from the static ribbons, and a square-well diffraction grating is formed along the long axis 414 of the array 402. In some embodiments, several ribbon pairs, each including one active and one static ribbon, are ganged under action of a single drive channel 410 to form a single MEMS pixel 416. By assembling a large number of MEMS pixels 416 and driver channels 410, the monolithic MEMS-based SLM 400 is operated as a continuous, programmable diffraction grating results, such as is particularly useful in imaging, printing and lithography applications.

In another embodiment, the array 402 consists entirely of active (movable) ribbons 406 and each modulator 404 consists of a number of active (movable) ribbons 406, such as shown in FIGS. 3A and 3B above, and the monolithic MEMS-based SLM 400 is configured or operable as a phase-array, capable of modulating the phase, amplitude or both of light incident on the array.

A schematic side view of a deflected active ribbon of the monolithic MEMS-based SLM 400 of FIG. 4A is shown in FIG. 4B. When a potential difference is applied between an active ribbon 406 and substrate 412 the active ribbon is deflected into a parabolic profile as shown. As a result the square-well diffraction grating is established in a narrow region near the center-line of the array 402 that is displaced by a λ/4. Regions outside this optical “sweet-spot” are neither parallel to the surface of the array 100 nor displaced by λ/4 and therefore cannot provide the desired high contrast and high efficiency modulation. For this reason, illumination onto the array 402 is carefully shaped or focused into a line of illumination 418. A typical rule of thumb is that the width (W) of the illumination 418 should be no more than about a tenth ( 1/10^{th}) of a length (L) of the ribbon 406.

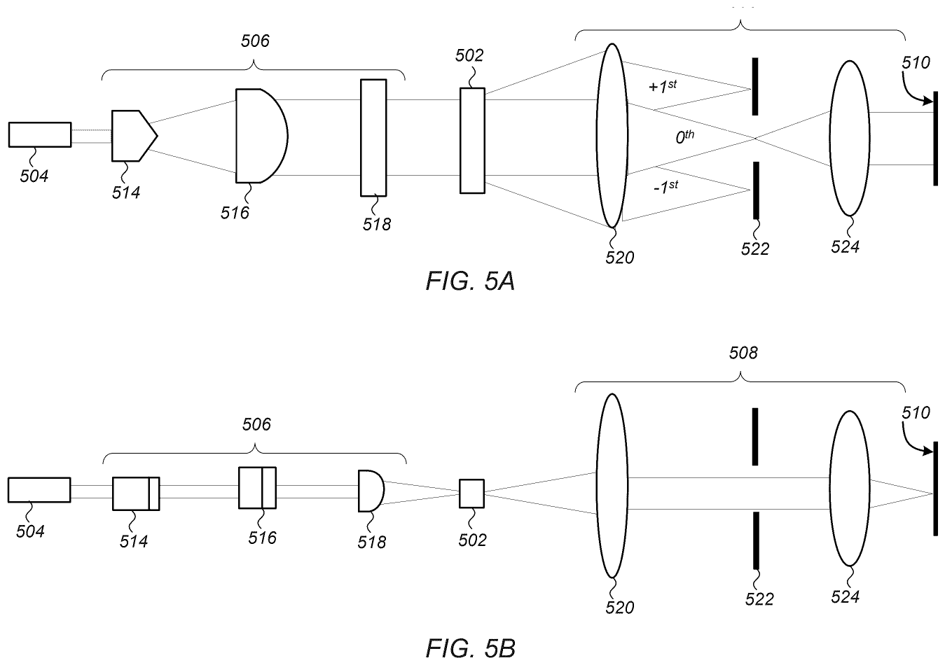

FIGS. 5A and 5B are optic diagrams illustrating illumination and imaging light paths for an optical system for illuminating a linear array of a monolithic a MEMS-based SLM including ribbon-type modulators. In particular, FIG. 5A is a top view illustrating the light paths along a vertical or longitudinal axis 414 of the linear array 402 shown in FIG. 4A, and FIG. 5B is a side view of the light path along a horizontal or short axis. For purposes of clarity and to simplify the drawings the optical light path is shown as being unfolded causing the linear array 502 to appear as transmissive. However, it will be understood that because the linear array 502 is reflective the actual light paths are folded at an acute angle relative to one another and the linear array.

Referring to FIGS. 5A and 5B, the light path begins at a light source 504, such as a laser, and passes through illumination optics 506, to illuminate a substantially linear portion of a linear array of the linear array 502 (shown as illumination 418 in FIGS. 4A and 4B), and imaging optics 508 to focus the modulated light onto an imaging surface 510 or objects in a far-field scene (not shown in this figure). Generally, the illumination optics 506 can include a Powell lens 514, a long axis collimating lens 516, and a cylindrical, short axis focusing lens 518 to substantially uniformly illuminate a rectangular portion of the linear array 502 with a light-beam. The imaging optics 508 generally includes a number of lenses and optical elements to direct amplitude or phase modulated light reflected from the linear array 502 onto an imaging surface 510 or objects in a far-field scene. In one embodiment, such as that shown, the imaging optics 508 includes a first Fourier Transform (FT) lens 520, a spatial filter, such as a Fourier aperture 522, to separate a 0^{th} order beam in the modulated light from +1st order beams and a second inverse Fourier Transform (FT) lens 524.

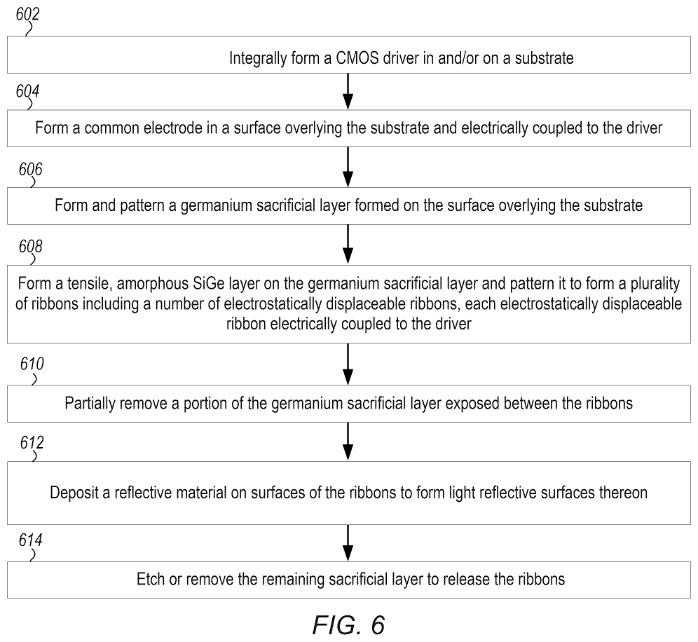

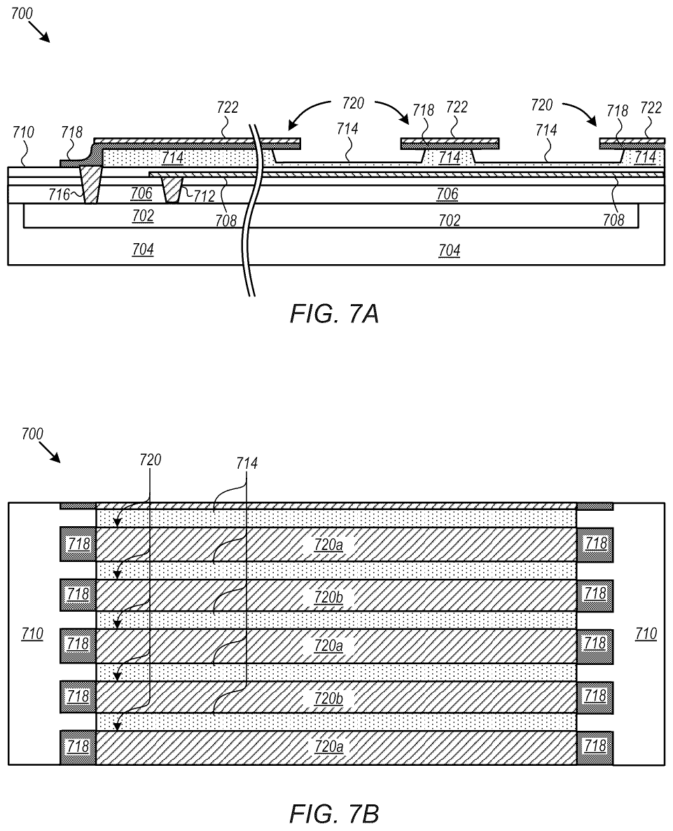

A method of fabricating a monolithic MEMS-based SLM including ribbon-type modulators and a driver integrally fabricated in or on a common substrate will now be described with reference to the flow chart of FIG. 6 and the intermediate MEMS structure 700 of FIGS. 7A and 7B.

Referring to FIGS. 6 and 7A and 7B, the method begins with integrally forming a CMOS driver 702 in and/or on a substrate 704 (step 602). Generally, the driver 702 includes multiple layers of vias, metal interconnect layers, and CMOS transistors or devices, formed in the substrate or in dielectric layers 706 overlying the substrate as shown in FIG. 1. The driver 702 is formed using standard semiconductor fabrication techniques, and in particular using CMOS technology.

Next, a common electrode 708 is formed in or a surface 710 overlying the substrate 704 and electrically coupled to the driver 702 through a via 712 (step 604).

A germanium sacrificial layer 714 is then formed on the surface 710 overlying the substrate 704 and patterned (step 606). Patterning the sacrificial layer 714 generally includes exposing a number of electrical contacts 716 through which ribbon electrodes in the subsequently formed electrostatically displaceable ribbons will be electrically coupled to the driver 702.

Referring to FIGS. 7A and 7B, a tensile, amorphous SiGe layer 718 is then formed on the sacrificial layer 714 and patterned to form a plurality of ribbons 720, including a number of electrostatically displaceable ribbons, each electrostatically displaceable ribbon electrically coupled to the driver 702 through one of the electrical contacts 716 (step 608). Note, the right side of FIG. 7A is rotated 90° to more clearly show a cross-section of the ribbons 720, while FIG. 7B shows a top view of the ribbons 720. Generally, the SiGe layer 718 is a conformal layer of silicon-germanium that completely cover the sacrificial layer 714 substantially without any voids and covers the electrical contacts 716.

In the embodiment shown in FIG. 7B the plurality of ribbons 720 includes a number of electrostatically displaceable ribbons 720a, interleaved or interdigitated with a number of static, bias ribbons 720b, resulting in a ribbon-type modulator as shown in FIG. 2A. However, it will be understood that alternatively all of the ribbons 720 can be electrostatically displaceable ribbons, resulting in a ribbon-type phase modulator as shown in FIG. 3A. In either embodiment, the electrostatically displaceable ribbons 720a are electrically coupled to the driver 702 through the electrical contacts 716.

As noted above, the SiGe layer 718 is formed by CVD or PECVD deposition at a low temperature of less than about 500 C to yield an amorphous SiGe layer, and is implanted with impurities and/or dopant ions at a concentration selected to change stress in the SiGe layer from a compressive stress to a tensile stress to form a tensile, amorphous SiGe layer. Generally, the SiGe layer 718 is annealed at a low temperature of less than about 500 C following the ion implant.

Next, a portion of the germanium sacrificial layer 714 exposed between the ribbons 720 is partially removed or gouged (step 610). Generally, as in the embodiment shown, the ribbons 720 are undercut to substantially prevent metal deposition on sidewalls of the germanium sacrificial layer 714 remaining under the ribbons in a subsequent metallization process. Preferably, the undercut is about 1 μm+/−0.2 μm, per side of the ribbon 720. Generally, the etch is accomplished using an isotropic wet etch process. In one embodiment the wet etch uses 30% hydrogen peroxide (H₂O₂) metal etch, followed by a post-etch residue remover, such as EKC265™ commercially available from DuPont.

A reflective surface 722 is formed on the ribbons 720 to yield the intermediate MEMS structure shown in FIGS. 7A and 7B (step 612). Generally, the reflective surface 722 is formed by depositing a thin layers of a reflective material, such as aluminum (Al), aluminum-copper (AlCu), gold (Au), silver (Ag) or any other suitably reflective metal, by a physical vapor deposition (PVD) process, such as sputtering.

Finally, the germanium sacrificial layer is etched or removed to release the ribbons 720, resulting in ribbon-type modulators as shown in FIG. 2A or 3A (step 614). As in step 610, the release can be accomplished using an isotropic wet etch process of 30% hydrogen peroxide (H₂O₂) metal etch, followed by a post-etch residue remover, such as EKC265™.

Thus, monolithic MEMS-based SLM including 2D MEMS-based modulators formed on a surface of a substrate overlying a driver integrally formed in the substrate below the modulators, have been disclosed. Embodiments of the present invention have been described above with the aid of functional and schematic block diagrams illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

It is to be understood that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The breadth and scope of the present invention should not be limited by any of the above-described exemplary embodiments, but should be defined only in accordance with the following claims and their equivalents.

What is claimed is:

1. A spatial light modulator (SLM), comprising:
a substrate including a common electrode; and
a plurality of ribbons suspended above a surface on the substrate, each ribbon comprising a tensile, amorphous silicon-germanium layer (SiGe layer) and a light reflective surface on the SiGe layer facing away from the surface on the substrate,
wherein the plurality of ribbons includes electrostatically displaceable ribbons, each electrostatically displaceable ribbon further comprising a ribbon electrode, and wherein each of the electrostatically displaceable ribbons is operable to be deflected towards the substrate in response to a drive voltage applied to the common electrode and the ribbon electrode.

2. The SLM of claim 1, further comprising a driver monolithically integrated in the substrate below the surface, the driver electrically coupled to the common electrode and the ribbon electrodes in the electrostatically displaceable ribbon, and operable to apply drive voltages thereto.

3. The SLM of claim 2, wherein the driver comprises a number of layers of vias, metal interconnect, and complementary metal-oxide-semiconductor (CMOS) devices.

4. The SLM of claim 3, wherein the SiGe layer in each of the ribbons is an implanted SiGe layer implanted with a concentration of impurities selected to change stress in the SiGe layer from a compressive stress to a tensile stress.

5. The SLM of claim 4, wherein the impurities implanted include dopants, and the implanted SiGe layer is conductive and functions as the ribbon electrode.

6. The SLM of claim 2, wherein the plurality of ribbons comprises static ribbons interdigitated with the electrostatically displaceable ribbons, and wherein the driver is operable to modulate an amplitude of light incident thereon by displacing the electrostatically displaceable ribbons so that light reflected from the light reflective surfaces of the electrostatically displaceable ribbons interferes with light reflected from the light reflective surfaces of the static ribbons.

7. The SLM of claim 6, wherein the driver is operable to electrostatically displace the electrostatically displaceable ribbons in an analog range of distances so that a gray-scale is achieved in the amplitude of the light reflected by the SLM.

8. The SLM of claim 7, wherein every ribbon in the plurality of ribbons is an electrostatically displaceable ribbon and the electrostatically displaceable ribbons are grouped into a plurality of pixels, each pixel including a number of adjacent electrostatically displaceable ribbons.

9. The SLM of claim 8, wherein the driver is operable to individually drive the number of adjacent electrostatically displaceable ribbons in each of the plurality of pixels to deflect each of the number of adjacent electrostatically displaceable ribbons in the pixel by a monotonically varying distance to modulate phases of light incident thereon.

10. The SLM of claim 9, wherein a maximum monotonically varying distance in the pixel is equal to half a wavelength of the light incident thereon.

11. The SLM of claim 9 wherein the SLM is operable to control the plurality of pixels to modulate both a phase and amplitude of light reflected from the light reflective surfaces of the pixel.

12. A phase modulator comprising:
a substrate including a common electrode;
an array of electrostatically displaceable ribbons suspended above a surface on the substrate, each ribbon comprising a tensile, amorphous silicon-germanium layer (SiGe layer) that serves as both a structural layer and as an ribbon electrode, and a light reflective surface on the SiGe layer facing away from the surface on the substrate; and
a driver monolithically integrated in the substrate below the surface, the driver electrically coupled to the common electrode and the ribbon electrodes in the electrostatically displaceable ribbons to apply a drive voltage therebetwen,
wherein the electrostatically displaceable ribbons are grouped to form a plurality of pixels, each pixel including a number of adjacent electrostatically displaceable ribbons, and wherein the driver is operable to individually drive the number of adjacent electrostatically displaceable ribbons in each of the plurality of pixels to deflect each of the number of adjacent electrostatically displaceable ribbons in the pixel by a monotonically varying distance to modulate a phase of light incident thereon.

13. The phase modulator of claim 12, wherein the SiGe layer in each of the electrostatically displaceable ribbons is a doped SiGe layer implanted with a concentration of impurities selected to change stress in the SiGe layer from a compressive stress to a tensile stress.

14. The phase modulator of claim 12, wherein the driver comprises a number of layers of vias, metal interconnects, and complementary metal-oxide-semiconductor (CMOS) devices.

15. The phase modulator of claim 12, wherein a maximum monotonically varying distance in the pixel is equal to half a wavelength of the light incident thereon.

16. The phase modulator of claim 12, wherein the driver is operable to control the plurality of pixels to modulate both a phase and amplitude of light reflected from the light reflective surfaces of the pixel.

17. An intermediate microelectromechanical systems (MEMS) structure comprising:
a substrate having integrally formed therein a driver including a plurality of vias, metal interconnect layers, and complementary metal-oxide-semiconductor (CMOS) devices;
a common electrode in a surface overlying the substrate and electrically coupled to the driver;
a patterned germanium sacrificial layer formed on the surface overlying the substrate; and
a silicon-germanium layer (SiGe layer) deposited on the patterned germanium sacrificial layer, and patterned to form a number of electrostatically displaceable ribbons, each ribbon electrically coupled to the driver,
wherein the SiGe layer is formed by deposition at less than about 500 C to yield an amorphous SiGe layer, and is implanted with impurities at a concentration selected to change stress in the SiGe layer from a compressive stress to a tensile stress to form a tensile, amorphous SiGe layer.

18. The intermediate MEMS structure of claim 17, further comprising:
a light reflective surface formed on the SiGe layer facing away from the surface on the substrate.
